(19) United States
(12) Patent Application Publication
(10) Pub. No.: US 2025/0174468 A1
(43) Pub. Date: May 29, 2025

(54) SUBSTRATE PROCESSING METHOD, MANUFACTURING METHOD, AND SUBSTRATE PROCESSING APPARATUS

(71) Applicant: SEMES CO., LTD., Cheonan-si (KR)

(72) Inventor: Yong Hoon HONG, Seoul (KR)

(73) Assignee: SEMES CO., LTD., Cheonan-si (KR)

(21) Appl. No.: 18/948,907

(22) Filed: Nov. 15, 2024

(30) Foreign Application Priority Data
Nov. 28, 2023 (KR) 10-2023-0167957

(51) Int. Cl. H01L 21/3213; H01L 21/02; H01L 21/67

(52) U.S. Cl. CPC H01L 21/32134; H01L 21/02068; H01L 21/6704; H01L 21/67075

(57) ABSTRACT

Disclosed is a method of processing a substrate, the method including: an etchant supply operation of supplying an etchant to remove a film on a substrate; and a removal liquid supply operation of supplying a removal liquid to remove impurities attached onto the substrate, after the etchant supply operation is performed, in which the removal liquid has conductivity in a set range.

### CROSS-REFERENCE TO RELATED APPLICATIONS

This application claims priority to and the benefit of Korean Patent Application No. 10-2023-0167957 filed in the Korean Intellectual Property Office on Nov. 28, 2023, the entire contents of which are incorporated herein by reference.

### TECHNICAL FIELD

The present invention relates to a substrate processing method, a manufacturing method, and a substrate processing apparatus.

### BACKGROUND ART

To manufacture semiconductor devices, various processes, such as photography, deposition, etching, and ion implantation, are performed on substrates, such as wafers.

Among these, the etching process is a process that removes a film formed on a substrate. The etching process may include an etching process as a narrow meaning that removes a film by using a mask or the like, and an etching process as a broad meaning that includes an ashing process that removes the mask left on the substrate after the etching process is performed.

The etching process includes a dry etching process that removes a film on a substrate using plasma or the like, and a wet etching process that removes a film on a substrate by supplying an etchant to the substrate. The wet etching process is performed by supplying an etchant to a rotating substrate. However, in this case, process by-products that may occur during the wet etching process may be re-deposited on the substrate. This problem may be more frequent when the etchant used to perform the wet etching process is recycled.

### SUMMARY OF THE INVENTION

The present invention has been made in an effort to provide a substrate processing method, a substrate manufacturing method, and a substrate processing apparatus capable of efficiently processing a substrate.

The present invention has also been made in an effort to provide a substrate processing method, a substrate manufacturing method, and a substrate processing apparatus capable of effectively supplying an etchant on a substrate and improving the efficiency of removing a film on a substrate.

The present invention has also been made in an effort to provide a substrate processing method, a substrate manufacturing method, and a substrate processing apparatus capable of effectively removing process by-products that may be reattached to the substrate.

The problem to be solved by the present invention is not limited to the above-mentioned problems, and the problems not mentioned will be clearly understood by those skilled in the art from the descriptions below.

An exemplary embodiment of the present invention provides a method of processing a substrate, the method including: an etchant supply operation of supplying an etchant to remove a film on a substrate; and a removal liquid supply operation of supplying a removal liquid to remove impurities attached onto the substrate, after the etchant supply operation is performed, in which the removal liquid has conductivity in a set range.

According to the exemplary embodiment, the etchant may be prepared by mixing a reused etchant and an unused etchant.

According to the exemplary embodiment, the removal liquid may be low concentration ammonia water with a concentration of 1.5 to 58 ppm.

According to the exemplary embodiment, the removal liquid may be a liquid having conductivity of 5 to 40 μS/cm.

According to the exemplary embodiment, the film may be formed from a material including any one of TiN, Co, Cu, AlO, AlN, tungsten doped carbon, and combinations thereof.

According to the exemplary embodiment, the method may further include wetting liquid supply operation of supplying a wetting liquid to heat the substrate to an upper portion of the substrate, prior to supplying the etchant.

According to the exemplary embodiment, polarity of the film may be more similar to polarity of the wetting liquid than the etchant.

According to the exemplary embodiment, the film may be formed from a material including TiN, and the wetting liquid may be isopropyl alcohol.

According to the exemplary embodiment, the wetting liquid supply operation may further include supplying a lower wetting liquid to a lower portion of the substrate to heat the substrate.

According to the exemplary embodiment, the lower wetting liquid may be deionized water or isopropyl alcohol.

According to the exemplary embodiment, the etchant may be a liquid including aqueous hydrogen peroxide, an organic chemical, a nucleophilic reducing agent, a pH regulator, a metal precipitation inhibitor, a chelating agent, and an organic solvent.

Another exemplary embodiment of the present invention provides a manufacturing method including: an etchant supply operation of supplying an etchant to remove a TiN film formed on a wafer; and a removal liquid supply operation of supplying a removal liquid to remove impurities attached to a metal surface that is exposable while removing the TiN film, the impurities being included in the etchant, the removal liquid supply operation being performed immediately after the etchant supply operation, in which the impurities are attached to the metal surface by static electricity, and the removal liquid has conductivity in a set range to remove the static electricity and separate the impurities from the metal surface.

According to the exemplary embodiment, the set range may be 5 to 40 μS/cm.

According to the exemplary embodiment, the removal liquid may be low concentration ammonia water with a concentration of 1.5 to 58 ppm.

According to the exemplary embodiment, the method may further include a wetting liquid supply operation of heating the wafer and forming a liquid film that is mixed with the etchant before or after the etchant supply operation.

Still another exemplary embodiment of the present invention provides an apparatus for processing a substrate, the apparatus including: a substrate support chuck for supporting and rotating a substrate; a cup surrounding at least a portion of the substrate support chuck, and recovering a liquid supplied to the substrate support chuck; a liquid supply unit including an etchant nozzle for supplying, to a top surface of the substrate placed on the substrate support chuck, an etchant to remove a film on the substrate and a removal liquid nozzle for supplying a removal liquid to the top surface of the substrate placed on the substrate support chuck, the removal liquid removing impurities electrostatically attached to the substrate; and a circulation unit for supplying the etchant to the etchant nozzle, in which the circulation unit includes: a recovery line for recovering a reused etchant recovered from a drain line connected with the cup; a recovery tank connected to the recovery line, and to a reservoir line supplying an unused etchant; a sub-tank for receiving the etchant including a mixture of the reused etchant and the unused etchant from the recovery tank, and adjusting a temperature of the etchant to a set temperature; and a main tank for receiving the etchant adjusted to the set temperature from the sub-tank and supplying the etchant to the etchant nozzle.

According to the exemplary embodiment, the apparatus may further include a three-way valve, in which the three-way valve may be connected with the drain line, the recovery line, and a discharge line for discharging at least a portion of the etchant drained through the drain line to the outside of the apparatus.

According to the exemplary embodiment, the apparatus may further include a controller for controlling the liquid supply unit and the etchant circulation unit, in which the controller is configured to generate a control signal to control the liquid supply unit and the substrate support chuck to perform: an etchant supply operation of supplying, by the etchant nozzle, the etchant to the substrate placed on the substrate support chuck; and the removal liquid supply operation of supplying, by the removal liquid nozzle, the removal liquid to the substrate placed on the substrate support chuck.

According to the exemplary embodiment, the controller may be configured to generate a control signal to control the three-way valve such that a portion of the etchant supplied by the etchant nozzle is discarded through the discharge line and another portion is recovered through the recovery line to the recovery tank.

According to the exemplary embodiment, the drain line may be provided in plurality, and when the etchant supply operation and the removal liquid supply operation are performed while overlapping, the controller may generate a control signal to control the three-way valve to discard the etchant and the removal liquid through the discharge line, and when the etchant supply operation and the removal liquid supply operation are performed without overlapping, the controller may control a lifting driver for lifting the cup so as to drain the etchant and the removal liquid from the cup through the different drain lines.

According to the exemplary embodiment of the present invention, it is possible to efficiently process a substrate.

Further, according to the exemplary embodiment of the present invention, it is possible to effectively supply an etchant onto a substrate, and improve efficiency of removing a film on the substrate.

Further, according to the exemplary embodiment of the present invention, it is possible to effectively remove process by-products that may be reattached to the substrate.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a top plan view of a substrate processing apparatus according to an exemplary embodiment of the present invention.

FIG. 2 is a cross-sectional view illustrating the substrate processing apparatus provided in a process chamber of FIG. 1.

FIG. 3 is a diagram illustrating a circulation unit for supplying an etchant to the liquid supply unit of FIG. 1 and circulating the used etchant.

FIG. 4 is a flow chart illustrating a substrate processing method according to an exemplary embodiment of the present invention.

FIG. 5 is a diagram illustrating a feature formed on a substrate processed through the substrate processing method of FIG. 4.

FIG. 6 is a diagram illustrating a view of the process chamber performing a wetting liquid supply operation of FIG. 4.

FIG. 7 is a diagram illustrating a view of the process chamber performing an etchant supply operation of FIG. 4.

FIG. 8 is a diagram illustrating a feature formed on the substrate after the etchant supply operation of FIG. 4 has been performed.

FIG. 9 is a diagram illustrating a view of the process chamber performing a removal liquid supply operation of FIG. 4.

FIG. 10 is a diagram illustrating a view of a feature formed on the substrate after the removal liquid supply operation of FIG. 4 has been performed.

FIG. 11 is a diagram illustrating a view of the process chamber performing the wetting liquid supply operation according to another exemplary embodiment of the present invention.

FIGS. 12 to 15 are flow charts illustrating a substrate processing method according to another exemplary embodiment of the present invention.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereinafter, a manufacturing method, a substrate processing method, and a substrate processing apparatus according to an exemplary embodiment of the present invention will be described in detail. The manufacturing method may be a method of manufacturing a semiconductor device. The substrate processing method may be processes corresponding to some of various processes required to manufacture the semiconductor device. Further, a substrate processing apparatus may be an apparatus for implementing the above substrate processing method for processing a substrate W, such as a wafer. Further, the substrate processing apparatus may correspond to a semiconductor device manufacturing apparatus capable of performing processes corresponding to some of the various processes required to manufacture the semiconductor devices described above.

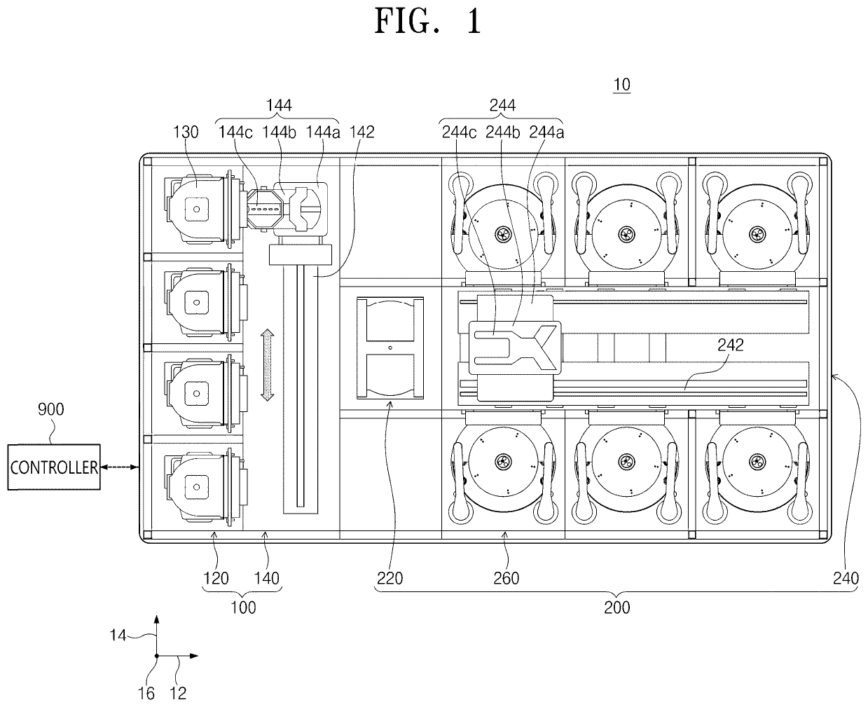

Hereinafter, exemplary embodiments of the present invention will be described in detail with reference to FIGS. 1 to 15.

FIG. 1 is a top plan view of a substrate processing apparatus according to an exemplary embodiment of the present invention.

Referring to FIG. 1, a substrate processing apparatus 10 includes an index module 100, a process processing module 200, and a controller 900. The Index module 100 includes a load port 120 and a transfer frame 140. The load port 120, the transfer frame 140, and the process processing module 20 are arranged in sequential rows. Hereinafter, a direction in which the load port 120, the transfer frame 140, and the process processing module 200 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 130 in which a substrate W is accommodated is seated on the load port 120. A plurality of load ports 120 is provided and is arranged in a line along the second direction 14. The number of load ports 120 may be increased or decreased depending on process efficiency and footprint requirements of the process processing module 200. The carrier 130 is formed with a plurality of slots (not illustrated) for receiving the substrates W in a horizontal position relative to the ground. As the carrier 130, a Front Opening Unified Pod (FOUP) may be used.

The process processing module 200 includes a buffer unit 220, a transfer chamber 240, and a process chamber 260. The transfer chamber 240 may disposed so that a longitudinal direction thereof is parallel to the first direction. The process chambers 260 may be disposed at opposite sides of the transfer chamber 240. On one side of the transfer chamber 240 and on the other side of the transfer chamber 240, the process chambers 260 are provided to be symmetrical with respect to the transfer chamber 240. On one side of the transfer chamber 240, a plurality of process chambers 260 are provided. Some of the process chambers 260 may be disposed in the longitudinal direction of the transfer chamber 240. Further, some of the plurality of process chambers 260 may be disposed to be stacked on each other. That is, the plurality of process chambers 260 may be disposed in an arrangement of A×B at one side of the transfer chamber 240. Here, A is the number of process chambers 260 provided in a line along the first direction 12, and B is the number of process chambers 260 provided in a line along the third direction 16. When four or six process chambers 260 are provided at one side of the transfer chamber 240, the process chambers 260 may be disposed in an arrangement of 2×2 or 3×2. The number of process chambers 260 may be increased or decreased. Unlike the foregoing, the process chamber 260 may be provided only to one side of the transfer chamber 240. In addition, the process chamber 260 may be provided as a single layer on one side and both sides of the transfer chamber 240.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. A slot (not illustrated) in which the substrate W is placed is provided inside the buffer unit 220. A plurality of slots (not illustrated) is provided so as to be spaced apart from each other in the third direction 16. A surface of the buffer unit 220 facing the transfer frame 140 and a surface of the buffer unit 220 facing the transfer chamber 240 may be opened.

The transfer frame 140 transfers the substrate W between the carrier 130 seated at the load port 120 and the buffer unit 220. An index rail 142 and an index robot 144 are provided to the transfer frame 140. A longitudinal direction of the index rail 142 is provided to be parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 130, and another some of the plurality of index arms 144c may be used when the substrate W is transferred from the carrier 130 to the process processing module 200. This may prevent particles generated from the substrate W before the process processing from being attached to the substrate W after the process processing in the process of loading and unloading the substrate W by the index robot 144.

The transfer chamber 2400 transfers the substrate W between the buffer unit 2200 and the process chamber 260, and between the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b. A plurality of main arms 244c is provided to be individually driven. The main arms 244c are disposed to be stacked in the state of being spaced apart from each other in the third direction 16.

The process chamber 260 performs a liquid treatment process on the substrate W. The liquid treatment process may be a wetting process (pre-processing process) in which the substrate W is heated and/or wet. Further, the liquid treatment process may be an etching process to remove some of the features formed on the substrate W. The liquid treatment process may also be a cleaning process (or post-processing process) to remove impurities on the substrate W. The process chambers 260 may have different structures depending on the type of liquid treatment process being performed. Alternatively, each of the process chambers 260 may have the same structure. Optionally, the process chambers 260 may be divided into a plurality of groups, such that process chambers 260 belonging to the same group may be provided with the same structure, and the process chambers 260 belonging to different groups may be provided with different structures.

The controller 900 may control the configurations of the substrate processing apparatus 10. The controller 900 may control the index module 100 and the process processing module 200. Further, the controller 900 may be configured to control the substrate processing apparatus provided in the process chamber 260.

Further, the controller 900 may include a process controller formed of a microprocessor (computer) that executes the control of the substrate processing apparatus 10, a user interface formed of a keyboard in which an operator performs a command input operation or the like in order to manage the substrate processing apparatus 10, a display for visualizing and displaying an operation situation of the substrate processing apparatus 10, and the like, and a storage unit storing a control program for executing the process executed in the substrate processing apparatus 10 under the control of the process controller or a program, that is, a treatment recipe, for executing the process in each component according to various data and processing conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

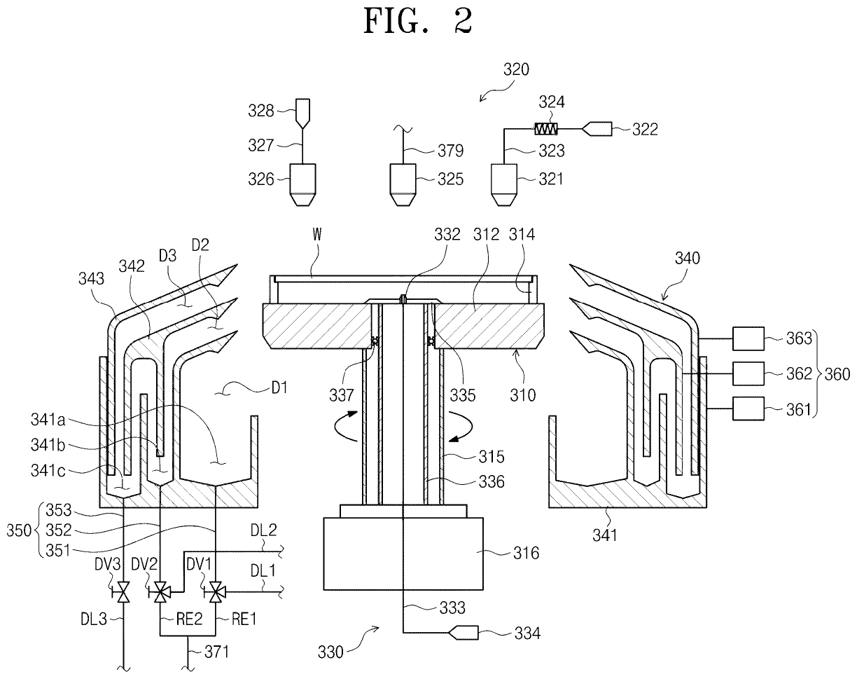

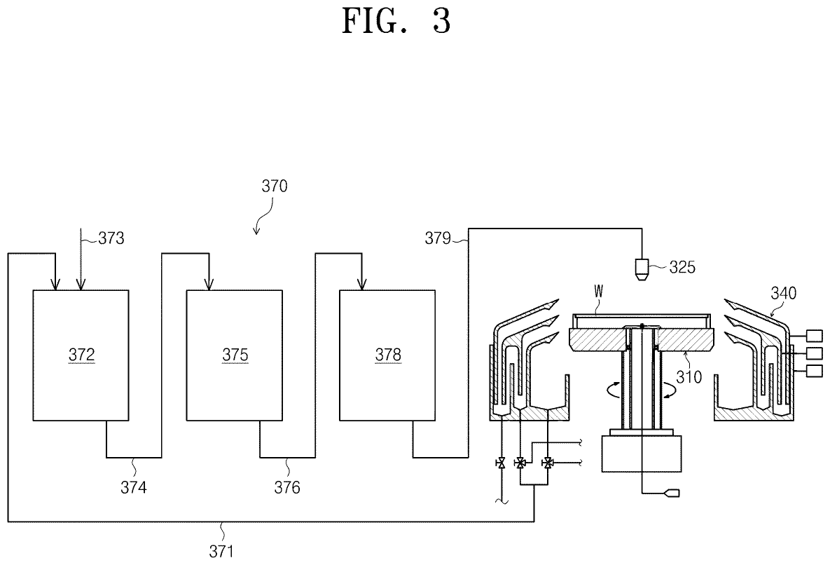

FIG. 2 is a cross-sectional view illustrating the substrate processing apparatus provided in a process chamber of FIG. 1, and FIG. 3 is a diagram illustrating a circulation unit for supplying an etchant to the liquid supply unit of FIG. 1 and circulating the used etchant.

Referring to FIGS. 2 and 3, the process chamber 260 may be provided with the substrate processing apparatus for liquid-treating the substrate W. The process chamber 260 may include a substrate support chuck 310, a first liquid supply unit 320, a second liquid supply unit 330, a cup 340, a drain line 350, a lifting driver 360, and a circulation unit 370.

The substrate support chuck 310 may support and rotate the substrate W. The substrate support chuck 310 may include a chuck body 312, a support pin 314, a rotating shaft 315, and a hollow motor 316.

The chuck body 312 may have a disk shape. The chuck body 312 may have an opening formed in a center region thereof. In the opening formed in the chuck body 312, some configurations of the second liquid supply unit 330 described later may be inserted. The chuck body 312 may be configured to be rotatable.

The support pin 314 may be installed on the chuck body 312. The support pin 314 may be installed on the top of the chuck body 312. The support pin 314 may be configured to support a lateral portion and a bottom portion of the substrate W. The support pin 314 may be configured to support an edge region of the substrate W. The top end of the support pin 314 may be configured to include a first face supporting a bottom surface of the substrate W and a second face supporting a lateral portion of the substrate W.

The support pin 314 may be moveable in a horizontal direction by a mechanical mechanism, which may include a motor, rails, or the like (not illustrated) as needed 314.

The rotating shaft 315 may be connected to a lower portion of the chuck body 312. The rotating shaft 315 may rotate the chuck body 312. The rotating shaft 315 may be provided as a hollow shaft. The rotating shaft 315 may be configured to have an inner diameter equal to or larger than that of an opening formed in the center region of the chuck body 312. The interior of the rotating shaft 315 may be provided for insertion of the liquid supply shaft 336 of the second liquid supply unit 330 described later.

An upper end of the rotating shaft 315 may be connected to the lower portion of the chuck body 312, and a lower end of the rotating shaft 315 may be connected to the hollow motor 316. The hollow motor 316 may rotate the rotating shaft 315. The hollow motor 316 may rotate the rotating shaft 315 to rotate the chuck body 312, which may rotate the substrate W placed on the support pin 314. As will be described later, the rotational force generated by the hollow motor 316 may not be transmitted to the liquid supply shaft 336, That is, the second liquid supply unit 330 described later may be independent of the rotation of the chuck body 312.

The first liquid supply unit 320 may supply a treatment liquid to the top surface of the substrate W. The second liquid supply unit 320 may supply a treatment liquid to the top surface of the substrate W to perform an etching process to remove a portion of the features formed on the substrate W. Further, the first liquid supply unit 320 may be configured to effectively process the substrate W by supplying a wetting liquid and a removal liquid before and after the etching process, respectively. The first liquid supply unit 320 may be an upper liquid supply unit that supplies the treatment liquid to the top surface of the substrate W.

The first liquid supply unit 320 may include a first upper nozzle 321, a second upper nozzle 325, and a third upper nozzle 326. Although not illustrated, the first upper nozzle 321, the second upper nozzle 325, and the third upper nozzle 326 may be configured to be movable in a vertical direction and a horizontal direction, respectively, on an upper portion of the substrate W. For example, the first upper nozzle 321, the second upper nozzle 325, and the third upper nozzle 326 may each be coupled to one end of a separate nozzle arm (not illustrated). The other end of the arm may receive rotational force from a motor or the like. That is, the first upper nozzle 321, the second upper nozzle 325, and the third upper nozzle 326 may be provided to change their positions in an imaginary arc with the other end of the arm as the axis of rotation when viewed from above. The first upper nozzle 321, the second upper nozzle 325, and the third upper nozzle 326 may each be provided to change its position between a process position (where the treatment liquid is supplied to the center of the substrate W) and a standby position (a position above a nozzle standby cup (not illustrated)).

However, the present invention is not limited thereto, and the first upper nozzle 321, the second upper nozzle 325, and the third upper nozzle 326 may all be installed on a single arm, or may be distributed over and installed in two arms. Furthermore, the positions of the first upper nozzle 321, the second upper nozzle 325, and the third upper nozzle 326 may be configured to be movable in a straight line direction by means of an LM guide or the like, without being limited to changing their positions in an imaginary arc.

The first upper nozzle 321 may supply a wetting liquid to the substrate W. The first upper nozzle 321 may receive the wetting liquid from the first upper liquid supply source 322 via a first upper liquid supply line 323. The first upper liquid supply line 323 may be equipped with a liquid heating heater 324 capable of heating the wetting liquid. The liquid heating heater 324 may be provided as a line heater provided to wrap around the exterior side of the first upper liquid supply line 323. The liquid heating heater 324 may be provided to heat the wetting liquid supplied by the first upper nozzle 321 so that the higher-temperature wetting liquid may be supplied to the substrate W.

The wetting liquid is formed on the substrate W described above and may have a polarity similar to the film to be removed. The wetting liquid may have a polarity closer to the film to be removed than the etchant described above. For example, the etchant may be hydrophilic and the wetting liquid may be hydrophobic. For example, the TiN film formed on the substrate W and to be removed may be hydrophobic. The wetting liquid may also be hydrophobic.

The wetting liquid may be an organic solvent. For example, the wetting liquid may be an organic solvent containing an alcohol. The wetting liquid may be isopropyl alcohol (IPA).

The second upper nozzle 325 may supply the etchant to the substrate W. The etchant may be configured to remove a film that is to be removed from a feature formed on the substrate W. The etchant may be formulated to include aqueous hydrogen peroxide, an organic chemical, a nucleophilic reducing agent, a pH adjuster, a metal precipitation inhibitor, a chelating agent, and an organic solvent. The etchant may be provided in a variety of etchants that are capable of removing metallic thin films containing metals.

Further, the second upper nozzle 325 may be connected to a supply line 379 of the circulation unit 370, which will be described later. The second upper nozzle 325 may supply the etchant supplied by the circulation unit 370 to the substrate W, which is supported and rotated on the substrate support chuck 310. The etchant supplied by the second upper nozzle 325 may be an etchant in which the reused etchant that has been used to process the substrate W and an unused etchant that has been newly added by a reservoir line 373 of the circulation unit 370 described later are mixed.

The third upper nozzle 326 may supply a removal liquid to the substrate W. The removal liquid may be a treatment liquid that removes impurities attached to the substrate W (for example, attached to the features formed on the substrate W). The removal liquid may be configured to remove impurities attached to the substrate W by static electricity. The removal liquid may be configured to have conductivity in a set range. The removal liquid may be a liquid having conductivity of 5 to 40 μS/cm. For example, the removal liquid may be a liquid having conductivity of 10 μS/cm. Additionally, the removal liquid may be low-concentration ammonia water. The low concentration ammonia water may be provided at a concentration of 1.5 to 58 ppm. For example, the low concentration ammonia water may be provided at a concentration of 3 ppm.

The third upper nozzle 326 may receive the removal liquid from the third upper liquid supply source 328 through the third upper liquid supply line 327. The third top nozzle 326 may receive the removal liquid from the third upper liquid supply source 328 and supply the removal liquid to the substrate W.

The second liquid supply unit 330 may supply a treatment liquid to the lower portion of the substrate W. The second liquid supply unit 330 may be a lower liquid supply unit. The second liquid supply unit 330 may include a lower nozzle 332, a second liquid supply line 333, a second liquid supply source 334, a cover 335, a liquid supply shaft 336, and a bearing 337.

The lower nozzle 332 may be installed on the cover 335 to face the bottom center region of the substrate W. The cover 335 may prevent the treatment liquids supplied to the substrate W from entering the rotating shaft 315 or the liquid supply shaft 336 through the hollow formed in the chuck body 312. The lower nozzle 332 may be provided within the liquid supply shaft 336 and may be connected to the second liquid supply line 333. The second liquid supply line 333 may be connected to the second liquid supply source 334, which may supply the treatment liquid supplied by the second liquid supply source 334 to the lower nozzle 332. The treatment liquid supplied by the second liquid supply source 334 may be an organic solvent, such as isopropyl alcohol (IPA), or deionized water (DI Water). The second liquid supply source 334 may also heat the treatment liquid and supply the heated treatment liquid to the lower nozzle 332.

In addition, a bearing 337 may be provided between the liquid supply shaft 336 and the chuck body 312. The outer surface of the liquid supply shaft 336 and the chuck body 312 may be spaced apart by the bearing 337. Further, the rotational force provided by the hollow motor 316 by the bearing 337 may not be transmitted to the liquid supply shaft 336. That is, the second liquid supply unit 330 may be independent of the rotation provided by the hollow motor 316.

The cup 340 may be provided to surround the substrate support chuck 310. The cup 340 may be configured to recover the treatment liquid supplied to the substrate W by the first liquid supply unit 320 and the second liquid supply unit 330.

The cups 340 may include a first cup 341, a second cup 342, and a third cup 343. The first cup 341 may be an inner cup. The first cup 341 may define a first drain space 341a, a second drain space 341b, and a third drain space 341c. The first drain space 341a, the second drain space 341b, and the third drain space 341c may be spaces for recovering the treatment liquids that are supplied to the substrate W and scattered. For example, the first drain space 341a may be a space for recovering the etchant. Further, the second drain space 341b may be a space for recovering the etchant. Further, the third drain space 341c may be a space for recovering the wetting liquid and the removal liquid.

The first drain space 341a may be located adjacent to the chuck 310, the second drain space 341b may be located further from the chuck 310 than the first drain space 341a, and the third drain space 341c may be located further from the chuck 310 than the second drain space 341b.

Additionally, the drain line 350 may discharge liquids collected in the drain spaces 341a and 341c described above to the outside. The drain line 350 may include a first drain line 351 connected to the first drain space 341a, a second drain line 352 connected to the second drain space 341b, and a third drain line 353 connected to the third drain space 341c.

The first drain line 351 may be connected to a first valve DV1. The first valve DV1 may be a three-way valve. The first valve DV1 may be connected to a first discharge line DL1 and a first recovery line RE1. the recovered treatment liquid may be discharged to the outside of the substrate processing apparatus through the first discharge line DL1, and the treatment liquid may be circulated to the circulation unit 370 for reuse of the recovered treatment liquid through the first recovery line RE1.

The second line 352 may be connected to a second valve DV2. The second valve DV2 may be a three-way valve. The second valve DV2 may be connected to a second discharge line DL2 and a second recovery line RE2. The recovered treatment liquid may be discharged to the outside of the substrate treatment unit through second discharge line DL2. The recovered treatment liquid may be circulated to the circulation unit 370 for reuse of the recovered treatment liquid through the second recovery line RE1.

The first recovery line RE1 and the second recovery line RE2 may be connected to a main recovery line 371 of the circulation unit 370 described later.

The third drain line 353 may be connected to a third valve DV3. The third valve DV3 may be a two-way valve. The third valve DV3 may be connected with a third discharge line DL3. The recovered treatment liquid may be discharged to the outside of the substrate treatment unit through the third discharge line DL3.

The second cup 342 may be a middle cup. The third cup 343 may be an outer cup. The first cup 341 may define a first recovery path D1 corresponding to the first drain space 341a. The first cup 341 and the second cup 342 may be combined with each other to define a second recovery path D2 corresponding to the second drain space 341b. The second cup 342 and the third cup 343 may be combined with each other to define a third recovery path D3.

The lifting driver 360 may lift the cups 340. The lifting driver 360 may lift the first cup 341, the second cup 342, and the third cup 343 independently of each other. The lifting driver 360 may include a first lifting driver 361 for lifting the first cup 341, a second lifting driver 362 for lifting the second cup 342, and a third lifting driver 363 for lifting the third cup 343. The lifting driver 360 may adjust the heights of the cups 351, 352, and 353 to adjust the heights of the recovery paths D1 and D2 described above, and the gap of the recovery paths D1 and D2.

The circulation unit 370 may circulate the treatment liquid supplied to the substrate W. The circulation unit 370 may supply the treatment liquid to the first liquid supply unit 320. The circulation unit 370 may recover the etchant supplied by the second upper nozzle 325 and circulate the recovered etchant.

Hereinafter, the etchant supplied by the second upper nozzle 325 is referred to as the supply etchant. In addition, the etchant recovered through the cup 340 is referred to as the reused etchant. Furthermore, the newly added etchant through the reservoir line 373 described later is referred as the unused etchant. The supply etchant may be a mixture of the reused etchant and the unused etchant.

The circulation unit 370 may include a main recovery line 371, a recovery tank 383, the reservoir line 373, a first connection line 374, a sub-tank 375, a second connection line 376, a main tank 378, and a supply line 379.

The main recovery line 371 may be connected to the first recovery line RE1 and the second recovery line RE2. The main recovery line 371 may recover the treatment liquid that is recovered through the cup 340. The main recovery line 371 may recover the used supply etchant via the cup 340.

The main recovery line 371 may be connected to a recovery tank 372. The recovery tank 372 recovers the reused etchant. The recovery tank 372 may have a space for recovering the treatment liquid. Further, the recovery tank 372 may be equipped with a concentration measurement sensor for measuring a concentration of the etchant, and a temperature measurement sensor for measuring a temperature of the etchant. In addition, the recovery tank 372 may be connected to the reservoir line 373 that supplies the unused etchant (new etchant). Further, the recovery tank 372 may be equipped with a heater for controlling the temperature of the etchant.

The controller 900 may generate a control signal to control the circulation unit 370 to supply the unused etchant via the reservoir line 373 and to control the temperature of the etchant via the heater so that the concentration and the temperature of the etchant measured by the concentration measurement sensor and the temperature measurement sensor reach a preset concentration and temperature.

Additionally, the recovery tank 372 may be equipped with a filter to filter process by-products that the reused etchant may include. However, the present invention is not limited thereto, and the filter may be installed in the main recovery line 371, or may be installed in both the recovery tank 372 and the main recovery line 371.

The supply etchant, which is a mixture of the reused etchant and the unused etchant may be delivered from the recovery tank 372 to the sub-tank 375 via the first connection line 374. In the sub-tank 375, the temperature of the supply etchant may be precisely controlled. The sub-tank 375 may be equipped with a temperature sensor for measuring the temperature of the etchant, and a heater for controlling the temperature of the etchant.

Since the recovery tank 372 may be continuously replenished with the unused etchant as well as the reused etchant, it may be difficult to precisely control the temperature of the etchant. Therefore, in the present invention, the separate sub-tank 375 is provided to precisely control the temperature of the etchant.

The temperature-controlled etchant may be delivered to the main tank 378 via the second connection line 376. In the main tank 378, a constant temperature may be maintained for the supplied etchant. The main tank 378 may be equipped with a temperature sensor to measure the temperature of the etchant, and a heater to control the temperature of the etchant. In the sub-tank 375, the temperature of the supply etchant may fluctuate as the temperature of the supply etchant is controlled. Accordingly, when the etchant is delivered to the second upper nozzle 325 directly from the sub-tank 375, the substrate W may be delivered with the etchant at the temperature during the temperature fluctuation rather than the desired temperature of the etchant.

In the exemplary embodiment of the present invention, the separate main tank 378 is provided to precisely maintain the temperature of the etchant, and to supply the precisely temperature maintained etchant to the substrate W.

The supply etchant, which is maintained at a desired temperature in the main tank 378, may be delivered to the second upper nozzle 325 via the supply line 379.

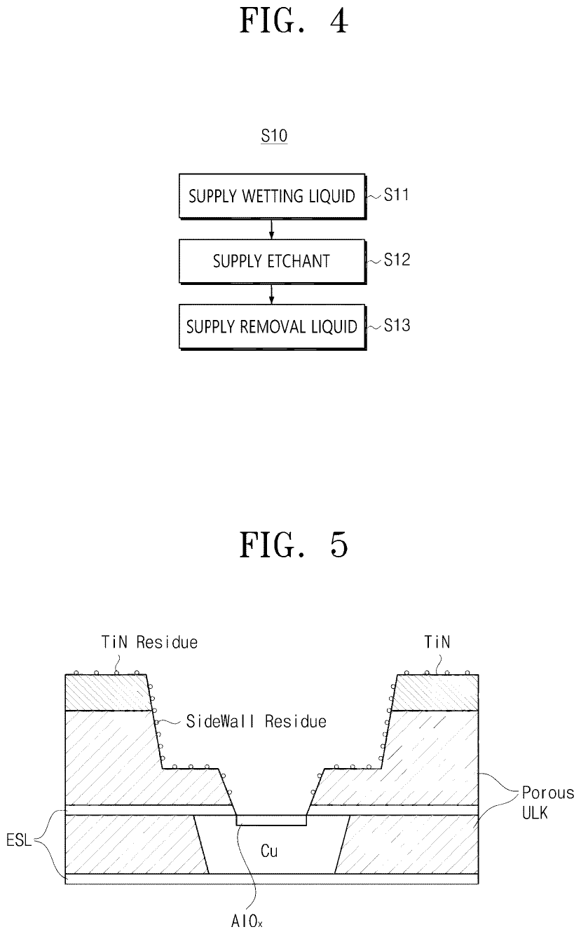

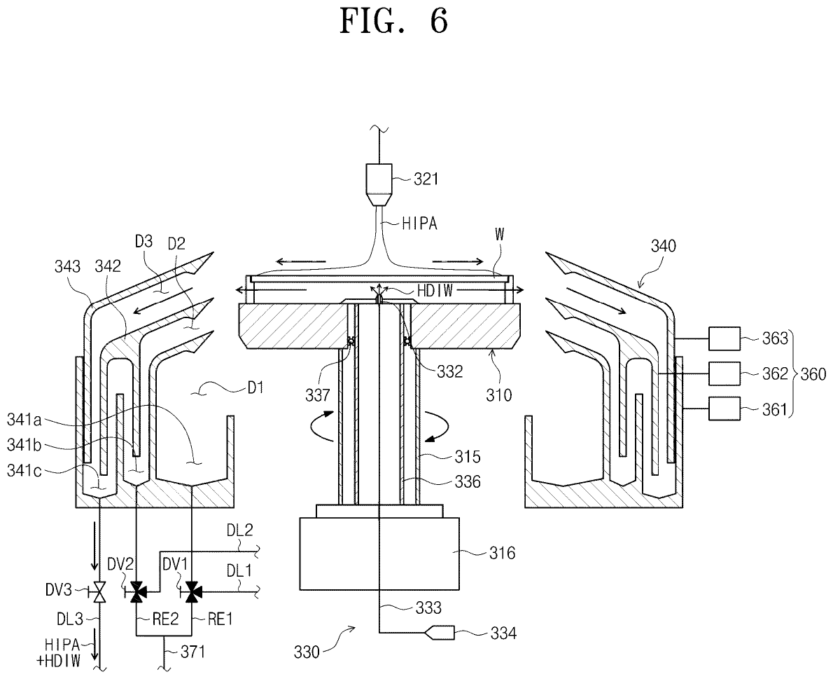

FIG. 4 is a flow chart illustrating a substrate processing method according to an exemplary embodiment of the present invention, and FIG. 5 is a diagram illustrating a feature formed on a substrate processed through the substrate processing method of FIG. 4.

Referring to FIGS. 4 and 5, a substrate processing method S10 according to an exemplary embodiment of the present invention may include removing a film on a feature formed on the substrate W.

The feature may include an anti-reflective film (Etch Stop Layer (ESL)), a porous insulating film (Porous Ultra Low K (ULK)), and a TiN film. In addition, a metallic film, a Cu film, may be formed on the porous insulating film, and an AlOx film may be formed on the surface of the Cu film, wherein the Cu film is tungsten doped. The TiN film and the porous insulating film may have TiN residue and sidewall residue attached thereto, respectively. The substrate processing method S10 according to the exemplary embodiment of the present invention aims to effectively remove (etch) the TiN film, the residue, and the AlOx.

The substrate processing method S10 according to the exemplary embodiment of the present invention may include a wetting liquid supply operation S11, an etchant supply operation S12, and a removal liquid supply operation S13.

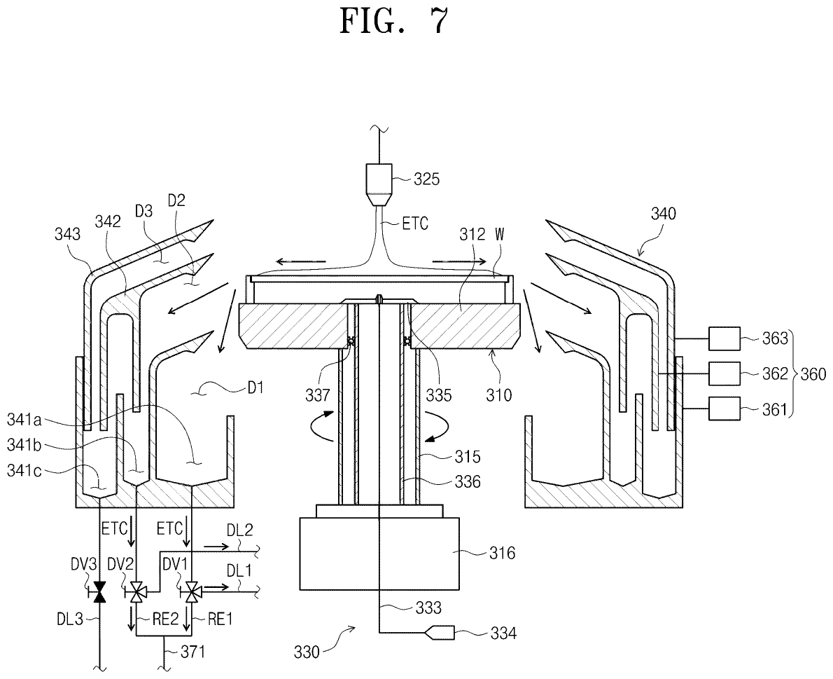

FIG. 6 is a diagram illustrating a view of the process chamber performing the wetting liquid supply operation of FIG. 4.

Referring to FIGS. 4 and 6, the wetting liquid supply operation S11 according to the exemplary embodiment of the present invention may include supplying a heated wetting liquid HIPA to a top surface of the rotating substrate W and supplying a heated lower wetting liquid HDIW to a lower surface of the substrate W. The wetting liquid HIPA and the lower wetting liquid HDIW may be different types of treatment liquids. For example, the wetting liquid HIPA may be heated isopropyl alcohol and the lower wetting liquid HDIW may be heated deionized water. The wetting liquid HIPA and the lower wetting liquid HDIW may be heated to a temperature capable of increasing a temperature of the substrate W and supplied. For example, the wetting liquid HIPA and the lower wetting liquid HDIW may be heated to a higher temperature than an etchant ETC described later and supplied to the substrate W. The wetting liquid HIPA may be supplied by the first upper nozzle 321 and the lower wetting liquid HDIW may be supplied by the lower nozzle 332. The wetting liquid HIPA and the lower wetting liquid HDIW may be recovered via the third recovery path D3 and discharged to the outside of the device via the third discharge line DL3.

Furthermore, the wetting liquid HIPA may have a polarity similar to that of the TiN film formed on the substrate W. The TIN film is hydrophobic. Therefore, when the etchant ETC is supplied immediately without supplying the wetting liquid HIPA, it may be difficult for the etchant ETC to be uniformly supplied onto the substrate W.

Therefore, the present invention provides a hydrophobic wetting liquid HIPA (i.e., similar in polarity to the TiN film than the etchant ETC), and first provides the wetting liquid HIPA toon the substrate W uniformly. Since the wetting liquid HIPA has a similar polarity to the TiN film, the wetting liquid HIPA may be uniformly supplied onto the substrate W. In the state where the wetting liquid HIPA is uniformly supplied, the etchant ETC described later is supplied while being mixed with the liquid-phase wetting liquid, so that the etchant ETC may also be uniformly supplied onto the substrate W. Furthermore, the reactivity of the film with the etchant ETC may be increased by the temperature increase of the substrate W by the wetting liquid HIPA and the lower wetting liquid HDIW. Accordingly, the film removal efficiency (etching efficiency) of the substrate W may be further improved.

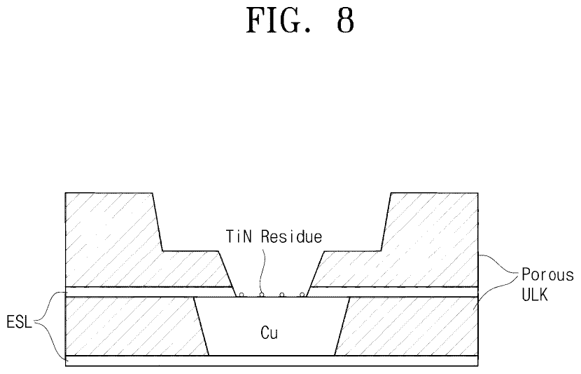

FIG. 7 is a diagram illustrating a view of the process chamber performing the etchant supply operation of FIG. 4.

Referring to FIGS. 4 and 7, the etchant supply operation S12 may include supplying the etchant ETC to the upper surface of the rotating substrate W to remove a film on the substrate. The etchant ETC may be supplied by the second upper nozzle 325. The etchant ETC may be recovered via the second recovery path D2 and/or the third recovery path D3.

Not all of the etchant ETC delivered to and used on the substrate W is delivered to the circulation unit 370, some may be discarded through the discharge lines DL1 and DL2 and some may be recovered via the recovery lines RE1 and RE2. The etchant ETC delivered to and used in the substrate W may have an increased temperature, and some of the used etchant ETC may be discarded, while other portions are reused. By discarding a portion of the used etchant ETC, it is easier to adjust the temperature of the etchant ETC in the circulation unit 370. By reducing the amount of impurities that need to be filtered out of the circulation unit 370, and by supplying a new etchant through the reservoir line 373, the degree of contamination of the etchant circulated through the circulation unit 370 may be maintained at a level appropriate for processing the substrate W.

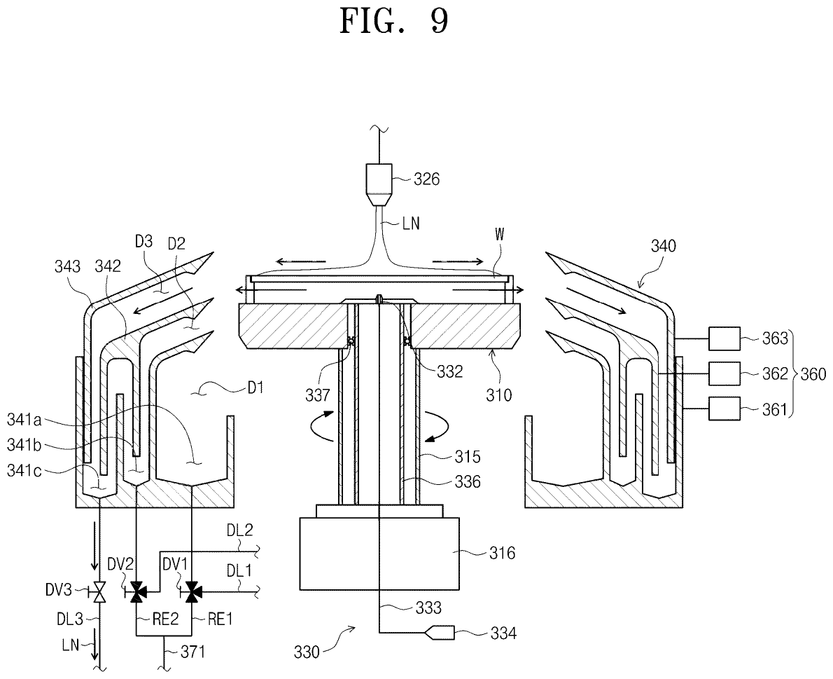

FIG. 8 is a diagram illustrating the feature formed on the substrate after the etchant supply operation of FIG. 4 has been performed. The etchant ETC may remove the TiN film, the AlOx film, and the residues, which the features formed on the substrate W include, and remove residues attached to the features. However, as described above, the etchant ETC supplied to the substrate W is prepared by mixing a reused etchant and an unused etchant. In other words, the etchant ETC includes a reused etchant. Most of the impurities in the reused etchant may be removed through filters or the like in the circulation unit 370, but some may not be removed. Furthermore, these impurities may be TiN residue generated while removing the TiN film.

When the etchant ETC is supplied, the TiN film, AlOx film, residue, and the like on the substrate (W) may be removed. When the AlOx film is removed by the etchant ETC, the surface of the Cu film may be exposed to the outside. In this case, TiN residue, which may be contained in the etchant, is electrostatically attached to the surface of the Cu film. Since these residues are electrostatically attached, the residues may be difficult to be removed by using general deionized water. Furthermore, the supply of the general deionized water may cause oxidation and corrosion on the exposed surface of the Cu film.

Therefore, the substrate processing method S10 according to the exemplary embodiment of the present invention may perform an etchant supply operation S12 and then a removal liquid supply operation S13.

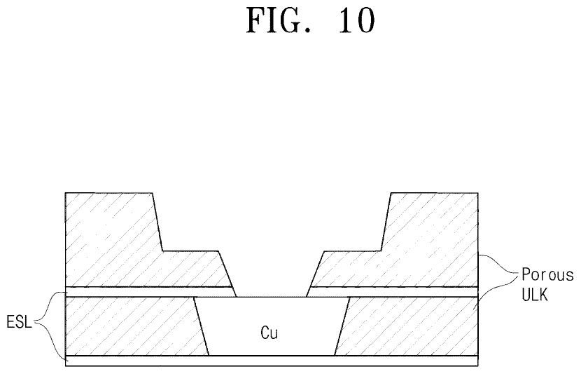

FIG. 9 is a diagram illustrating a view of the process chamber performing the removal liquid supply operation of FIG. 4.

Referring to FIGS. 4 and 9, the removal liquid supply operation S13 may include supplying a removal liquid LN to the rotating substrate W by the third upper nozzle 326. The removal liquid LN may be recovered via the third recovery path D3. The removal liquid LN recovered via the third recovery path D3 may be discharged to the outside of the apparatus via the third discharge line DL3.

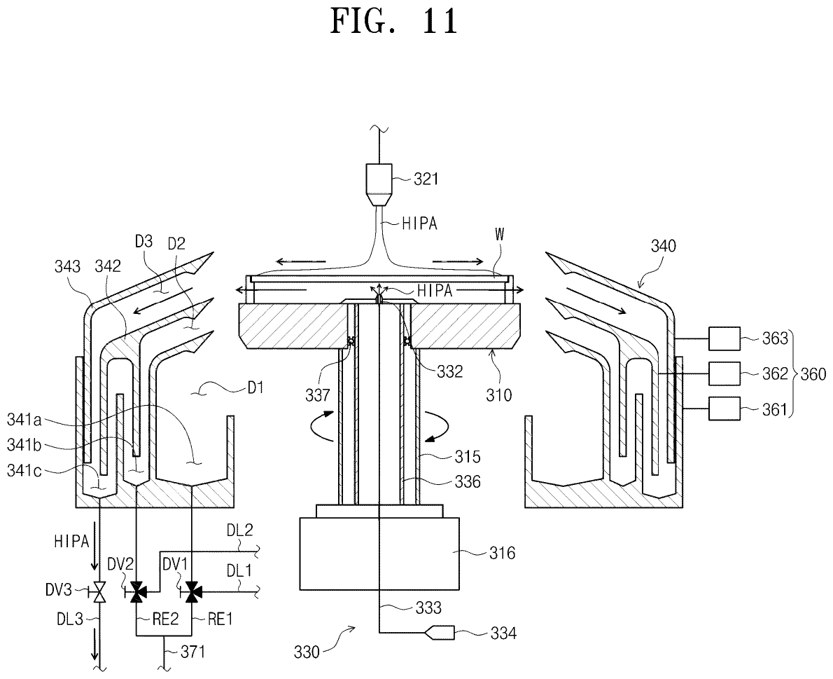

FIG. 10 is a diagram illustrating a view of a feature formed on the substrate after the removal liquid supply operation of FIG. 4 has been performed.

After the removal liquid supply operation S13 is performed, the TiN residue attached to the surface of the Cu film on the substrate W may be removed. This may be possible because the removal liquid LN is a liquid having conductivity in the set range. The removal liquid LN may have conductivity of 5 to 40 μS/cm. For example, the removal liquid LN may have conductivity of 10 μS/cm. The conductivity of the removal liquid LN may remove the static electricity that attaches the TiN residue, thereby effectively separating the TiN residue from the surface of the Cu film.

Additionally, the removal liquid LN may be low concentration ammonia water. For example, the removal liquid LN may be low concentration ammonia water having a concentration of 1.5 to 58 ppm. For example, the removal liquid LN may be low-concentration ammonia water having a concentration of 3 ppm. When the removal liquid LN has the concentration between 1.5 and 58 ppm, the removal liquid LN may have constant conductivity and may have substantially neutral properties. When the removal liquid LN has a strongly acidic or strongly basic nature, it may damage the Cu film itself in the process of removing the TiN residues attached to the Cu film.

After long experiments, the inventors of the present invention confirmed that when the removal liquid LN is a low-concentration ammonia water with a concentration of 1.5 to 58 ppm, and in particular, the removal liquid LN is a low-concentration ammonia water with a concentration of 3 ppm, the removal liquid LN has a very good effect of removing the static electricity that attaches the TiN residue and not damaging the Cu film.

In the substrate processing method S10 according to the exemplary embodiment of the present invention, the substrate W is heated by supplying a wetting liquid HDIW. In addition, the wetting liquid HDIW may be supplied before the etchant ETC to form a liquid film on the TiN film to solve the problem that the etchant ETC cannot effectively remove the TiN film due to the polarity difference between the etchant ETC and the TiN film. Since the liquid film formed by the HDIW is liquid, the liquid film may be effectively mixed with the ETC. This allows the ETC to be uniformly supplied to the TiN film.

In other words, the etchant ETC includes a reused etchant. Accordingly, the etchant ETC may include a process by-product (TiN residue) generated while removing the TiN film. The process by-product may be electrostatically attached to the exposed surface of the Cu film as the AlOx is removed.

To remove the above process by-products, the present invention supplies the removal liquid LN, which is low concentration ammonia water. The removal liquid LN removes the static electricity described above, thereby separating the process by-product from the surface of the Cu film. Furthermore, since the removal liquid LN is provided as low-concentration ammonia water, the removal liquid LN may have a substantially neutral nature, thus minimizing damage to the externally exposed Cu film. To perform the above functions, the removal liquid LN may be provided as low concentration ammonia water having a concentration of 1.5 to 58 ppm and conductivity of 5 to 40 μS/cm, and preferably, the removal liquid LN may be provided as low concentration ammonia water having a concentration of 3 ppm and conductivity of 10 μS/cm.

Table 1 below shows the experimental etch rates and particle levels for the case where the film was removed by supplying the etchant ETC followed by general deionized water (Comparative Example) and the case where the film was removed by sequentially supplying the wetting liquid HIPA, the etchant ETC, and the removal liquid LN (Example).

In the experiments, the substrate processing according to the Comparative Example and the Example was performed with TiN, Co, Cu, AlO, AlN, and Tungsten Doped Carbon (WDC) wafer as the films to be removed.

TABLE 1

| | | | | | | | P/C |
|---|---|---|---|---|---|---|---|
| | | | | | | | (Bare Si |
| Item | TiN | Co | Cu | AlO | AlN | WDC | Wafer) |
| Etchant- | 200.5 | −1.1 | 0.6 | 1.8 | 13.1 | 74.7 | 24 ea |
| deionized | | | | | | | @19 nm |
| water | | | | | | | |
| (Compar- | | | | | | | |
| ative | | | | | | | |
| Example) | | | | | | | |
| Wetting | 221.4 | −1.0 | .07 | 2.1 | 13.5 | 79.7 | 18 ea |
| liquid- | | | | | | | @19 nm |
| etchant | | | | | | | |
| removal | | | | | | | |
| liquid | | | | | | | |
| (Example) | | | | | | | |

As may be seen in Table 1 above, it may be seen that in the substrate processing method S10 according to the exemplary embodiment of the present invention, the etch rates for TiN, Co, Cu, AlO, AlN, and Tungsten Doped Carbon (WDC) wafer were improved and the particle level were also improved to a large extent from 24 to 18, compared to the substrate processing method according to the Comparative Example.

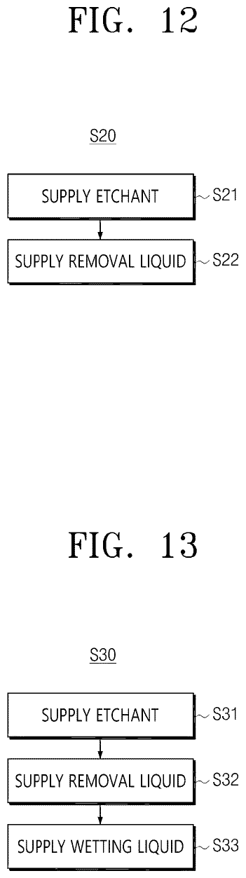

In the example described above, the present invention has been described based on the case where the deionized water is supplied to the lower portion of the substrate W in the wetting liquid supply operation S11 as an example, but is not limited thereto. For example, as illustrated in FIG. 11, the wetting liquid supply operation S11 may also supply heated isopropyl alcohol (HIPA) to the lower portion of the substrate W.

In addition, the inventor conducted the experiments on various process conditions in connection with the present invention, as shown in Table 2 below.

TABLE 2

| | | Whether a defect occurs |
|---|---|---|
| | | * Defect: when the number of |
| | | particles detected exceeds the |
| No. | Process condition | preset number |
| 1 | Etchant - Deionized Water | Defect Occurrence |
| 2 | Etchant - Low concentration ammonia | No defect |
| | water | |
| 3 | Etchant - Deionized Water - Heated | Defect Occurrence |
| | IPA | |
| 4 | Etchant - Low concentration ammonia | No defect |
| | water - Heated IPA | |
| 5 | Etchant - Deionized Water - Low | Defect Occurrence |
| | concentration ammonia water - Heated | |
| | IPA | |
| 6 | Low concentration ammonia water - | Defect Occurrence |
| | Etchant - Deionized Water - Heated | |
| | IPA | |
| 7 | Low concentration ammonia water - | No defect |
| | Etchant - Low concentration ammonia - | |
| | Heated IPA | |
| 8 | Heated IPA - Etchant - Deionized | Defect Occurrence |
| | Water - Heated IPA | |
| 9 | Heated IPA - Etchant - Low | No defect |
| | concentration ammonia water - | |
| | Heated IPA | |
| 10 | Heated IPA - Etchant - Deionized | Defect Occurrence |
| | Water - Low concentration ammonia | |
| | water - Heated IPA | |

As shown in the table above, it may be seen that defects do not occur when low-concentration ammonia water is supplied after the etchant is supplied. In particular, referring to Case No. 5 and Case No. 10, it may be seen that it is most desirable to supply low-concentration ammonia water immediately after supplying the etchant in order to prevent defects from occurring.

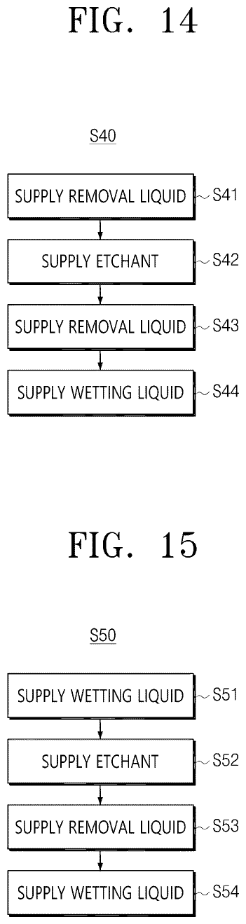

Referring to the above defect-free case, the present invention may contemplate a substrate processing methods according to other exemplary embodiment as illustrated in FIGS. 12 to 15.

For example, such as a substrate processing method S20 illustrated in FIG. 12, an etchant supply operation S21 and a removal liquid supply operation S22 may be performed sequentially.

Further, such as a substrate processing method S30 illustrated in FIG. 13, an etchant supply operation S31, a removal liquid supply operation S32, and a wetting liquid supply operation S33 may be performed sequentially.

Further, such as a substrate processing method S40 illustrated in FIG. 14, a removal liquid supply operation S41, an etchant supply operation S42, a removal liquid supply operation S43, and a wetting liquid supply operation S44 may be performed sequentially.

Further, such as a substrate processing method S50 illustrated in FIG. 15, a wetting liquid supply operation S51, an etchant supply operation S52, a removal liquid supply operation S53, and a wetting liquid supply operation S54 may be performed sequentially.

In the example described above, the present invention has been described based on the case where the etchant supply operation S12 and the removal liquid supply operation S13 are performed without overlapping, and the etchant ETC and the removal liquid LN are drained from the cup 340 through different drain lines 350 as an example.

However, the present invention is not limited thereto, and the etchant supply operation S12 and the removal liquid supply operation S13 may be performed in part overlapping.

For example, the second upper nozzle 325 may be moved in a scan outward direction from the center of the substrate W while supplying the etchant ETC, and the third upper nozzle 326 may supply the removal liquid LN to the center of the substrate W while the second upper nozzle 325 is being moved. In this case, the etchant ETC and the removal liquid LN may be recovered to the recovery path(s) selected from the first to third the recovery paths D1, D2, and D3 formed by the cup 340. In this way, when the etchant supply operation and the removal liquid supply operation are performed while overlapping, the treatment liquids recovered during the overlapping operation may be discarded via the discharge lines DL1, DL2, and DL3 without being circulated to the circulation unit 370, thereby preventing the removal liquid LN from being circulated to the circulation unit 370.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A method of processing a substrate, the method comprising:
an etchant supply operation of supplying an etchant to remove a film on a substrate; and
a removal liquid supply operation of supplying a removal liquid to remove impurities attached onto the substrate, after the etchant supply operation is performed,
wherein the removal liquid has conductivity in a set range.

2. The method of claim 1, wherein the etchant is prepared by mixing a reused etchant and an unused etchant.

3. The method of claim 2, wherein the removal liquid is low concentration ammonia water with a concentration of 1.5 to 58 ppm.

4. The method of claim 2, wherein the removal liquid is a liquid having conductivity of 5 to 40 μS/cm.

5. The method of claim 1, wherein the film is formed from a material including any one of TiN, Co, Cu, AlO, AlN, tungsten doped carbon, and combinations thereof.

6. The method of claim 1, further comprising:
a wetting liquid supply operation of supplying a wetting liquid to heat the substrate to an upper portion of the substrate, prior to supplying the etchant.

7. The method of claim 6, wherein polarity of the film is more similar to polarity of the wetting liquid than the etchant.

8. The method of claim 7, wherein the film is formed from a material including TiN, and
the wetting liquid is isopropyl alcohol.

9. The method of claim 6, wherein the wetting liquid supply operation further includes supplying a lower wetting liquid to a lower portion of the substrate to heat the substrate.

10. The method of claim 9, wherein the lower wetting liquid is deionized water or isopropyl alcohol.

11. The method of claim 1, wherein the etchant is a liquid including aqueous hydrogen peroxide, an organic chemical, a nucleophilic reducing agent, a pH regulator, a metal precipitation inhibitor, a chelating agent, and an organic solvent.

12. A manufacturing method comprising:
an etchant supply operation of supplying an etchant to remove a TiN film formed on a wafer; and
a removal liquid supply operation of supplying a removal liquid to remove impurities attached to a metal surface that is exposable while removing the TiN film, the impurities being included in the etchant, the removal liquid supply operation being performed immediately after the etchant supply operation,
wherein the impurities are attached to the metal surface by static electricity, and the removal liquid has conductivity in a set range to remove the static electricity and separate the impurities from the metal surface.

13. The manufacturing method of claim 12, wherein the set range is 5 to 40 μS/cm.

14. The manufacturing method of claim 12, wherein the removal liquid is low concentration ammonia water with a concentration of 1.5 to 58 ppm.

15. The manufacturing method of claim 12, further comprising:
a wetting liquid supply operation of heating the wafer and forming a liquid film that is mixed with the etchant before or after the etchant supply operation.

16. (canceled)

17. (canceled)

18. (canceled)

19. (canceled)

20. (canceled)
